(19) United States
(12) Patent Application Publication
(10) Pub. No.: US 2012/0074391 A1
(43) Pub. Date: Mar. 29, 2012

(54) DISPLAY DEVICE

(75) Inventors: Noa Sumida, Chiba-shi (JP); Kiyofumi Sakaguchi, Mobara-shi (JP); Toshinori Hasegawa, Yokohama-shi (JP); Yojiro Matsuda, Kawasaki-shi (JP)

(73) Assignee: CANON KABUSHIKI KAISHA, Tokyo (JP)

(21) Appl. No.: 13/229,413

(22) Filed: Sep. 9, 2011

(30) Foreign Application Priority Data
Sep. 24, 2010 (JP) 2010-213896
Jul. 27, 2011 (JP) 2011-164381

(51) Int. Cl. H01L 27/32

(52) U.S. Cl. 257/40; 257/E27.119

(57) ABSTRACT

A pixel unit having two or more pixels different in emission color is provided with lenses in such a manner that the difference of the angular dependence of brightness in organic EL elements for every emission color of the pixels becomes small.

### BACKGROUND OF THE INVENTION

1. Field of the Invention

The present invention relates to a display device having organic EL elements.

2. Description of the Related Art

In recent years, the display device having organic EL elements has been actively researched and developed. The organic EL element is constituted by an anode, an organic compound layer containing a light emitting layer, and a cathode, in which a hole and an electron are injected into the light emitting layer from the anode and the cathode, respectively, so that a light beam is emitted from the light emitting layer utilizing the recombination energy of the hole and the electron.

In order to achieve color display, a display device having two or more organic EL elements that emit different colors of red, green, and blue, for example, displays white color by making the organic EL elements of the respective colors emit a light beam. However, since the organic EL elements of the respective colors (red, green, and blue) are different from each other in the angular dependence of brightness, there has been a problem in that the white color chromaticity is different between the case where the display device is observed from the front and the case where the display device is observed at an angle inclining from the front (white color shift).

The description is specifically given with reference to FIG. 9. FIG. 9 is a graph showing the changes in the relative brightness to the radiation angle of the organic EL elements of red (R), green (G), and blue (B). The relative brightness is indicated under the conditions where the brightness at the front (0 angle) is 1. In FIG. 9, when the radiation angle is 50°, the relative brightness of the red color is about 0.55 and, in contrast, the relative brightness of each of the green color and the blue color is about 0.42 and about 0.30, respectively. Therefor, even when white color is observed when the display device is observed from the front, when the display device is observed at an angle inclining from the front, reddish white is observed because the relative brightness of the red color is larger than that of the other colors.

In order to address the problem, Japanese Patent Laid-Open No. 2009-123404 discloses that, in an organic EL element that causes multiple interference of light beams emitted from light emitting layers between the reflection planes of an anode and a cathode, the order of interference of a blue organic EL element is set to zero and functional layers other than the light emitting layers are made the same in the organic EL elements of the respective colors, whereby the difference in the angular dependence of brightness of the respective colors is suppressed.

However, it is difficult to control the film thickness of the organic compound layer constituting the organic EL element and it is difficult to form the organic EL element as designed while suppressing the in-plane variation of the functional layers which are thin films and further considering the interference.

### SUMMARY OF THE INVENTION

The present invention is a display device in which two or more pixel units containing two or more pixels different in the emission color are arranged, in which the pixels have an organic EL element and the pixel units are provided with a lens in such a manner that the difference in an angular dependence of brightness in the organic EL element for every emission color of the pixels becomes small.

Further features of the present invention will become apparent from the following description of exemplary embodiments with reference to the attached drawings.

### BRIEF DESCRIPTION OF THE DRAWINGS

FIGS. 1A and 1B are a perspective schematic view and a partial sectional schematic view, respectively, illustrating an example of a display device according to a first embodiment of the invention.

FIG. 2 is a partial sectional schematic view of a former display device.

FIG. 3 is a graph showing the correlation between the radiation angle and the relative brightness.

FIGS. 4A to 4E are views illustrating manufacturing processes of the display device according to the first embodiment of the invention.

FIG. 5 is a partial sectional schematic view illustrating a display device according to a second embodiment of the invention.

FIG. 6 is a partial sectional schematic view of a display device according to a third embodiment of the invention.

FIG. 7 is a graph showing the correlation between the radiation angle of and the relative brightness of a display device according to an Example of the invention.

FIGS. 8A to 8C are views illustrating manufacturing processes of the display device according to the third embodiment of the invention.

FIG. 9 is a graph showing the problems to be solved of the invention.

### DESCRIPTION OF THE EMBODIMENTS

Hereinafter, embodiments of a display device according to the invention will be described with reference to the drawings. To portions that are not particularly illustrated or described in this description, well known or known techniques of the technical field are applied. The embodiment described below is one embodiment of the invention and the invention is not limited thereto.

In the invention, the angular dependence of brightness refers to a property such that, the brightness (relative brightness) when a display device is observed at an angle inclining from the front changes to the brightness when the display device is observed from the front. Reducing the difference in the angular dependence of brightness refers to bringing changes in the relative brightness depending on the observation angle close to each other.

### First Embodiment

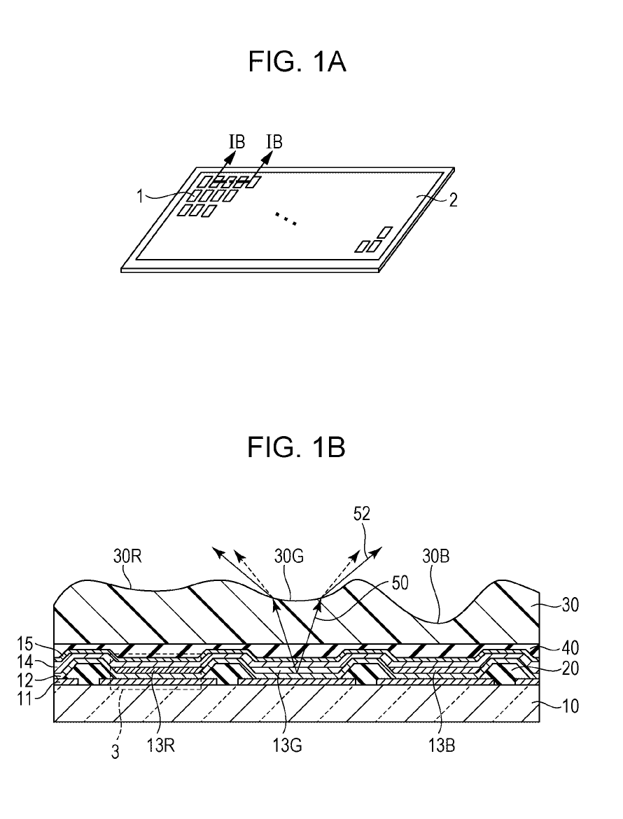

FIG. 1A is a perspective schematic view illustrating a display device according to a first embodiment of the invention. The display device of this embodiment has two or more pixels 1 each having an organic EL element. The two or more pixels 1 are disposed in the shape of a matrix and form a display region 2. The pixel refers to a region corresponding to a light emitting region of one light emitting element. In the display device of this embodiment, the light emitting element is an organic EL element and the display device of this embodiment is a display device in which an organic EL element of one color is disposed in each of the pixels 1. As the emission color of the organic EL elements, red, green, and blue can be considered and, in addition, yellow, cyan, and white may be acceptable. The color is not particularly limited insofar as at least two or more colors are employed. In the display device of this embodiment, two or more pixel units containing two or more pixels different in the emission color differs (e.g., a pixel emitting red, a pixel emitting green, and a pixel emitting blue) are arranged. The pixel unit refers to the minimum unit that can achieve light emission of a desired color by mixing the colors of the respective pixels.

FIG. 1B is a partial sectional schematic view along the IB-IB line of FIG. 1A. The pixel 1 has an organic EL element 3 having a first electrode (anode) 11, a hole transporting layer 12, any one of light emitting layers 13R, 13G, and 13B, an electron transporting layer 14, and a second electrode (cathode) 15 on a substrate 10. In this embodiment, the light emitting layer 13R is a light emitting layer that emits red, the light emitting layer 13G is a light emitting layer that emits green, and the light emitting layer 13B is a light emitting layer that emits blue. The light emitting layers 13R, 13G, and 13B are patterned and formed corresponding to the pixels (organic EL elements 3) that emits red, green, and blue, respectively. The first electrode 11 is also separated from the first electrode 11 of the next pixel (organic EL element 3). The hole transporting layer 12, the electron transporting layer 14, and the second electrode 15 may be formed in common to those of the next pixel or may be patterned for every pixel. In order to prevent a short circuit between the first electrode 11 and the second electrode 15 due to foreign substances, an insulating layer 20 is provided between the pixels (more specifically the first electrodes 11).

The display device of this embodiment is further provided with a lens member 30. Between the lens member 30 and each of the organic EL elements 3, a protection layer 40 that protects the organic EL elements 3 from moisture or oxygen is disposed. The lens member 30 has a concave portion on the surface and concave lenses 30R, 30G, and 30B are disposed corresponding to the respective pixels. The radius of curvature of each of the concave lenses 30R, 30G, and 30B is adjusted in such a manner as to be different from each other. Due to the configuration, the radiation characteristics of the lens can be changed for every pixel. In the invention, the difference in the angular dependence of brightness of the organic EL elements different in the angular dependence of brightness is made small by adjusting the radiation characteristics of the lens for every color. A specific description is given below. The “radiation characteristics” refer to characteristics with which the radiation angle of a light beam to be emitted is larger than the incidence angle of a light beam that enters an interface. The radiation characteristics can be controlled also by a region occupied by the lens of the region of the pixel, the radius of curvature (or curvature) of the lens, the distance from the light emitting layer (organic EL element) to the lens, and the refractive index of materials of the lens.

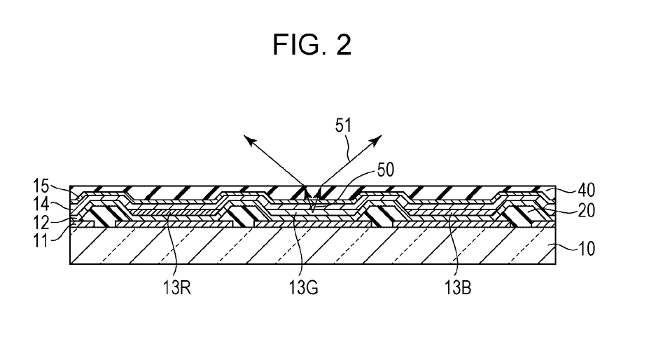

First, as illustrated in FIG. 2, the case where no lenses are formed in the pixels is considered. Light beams 50 obliquely emitted from the organic EL element are emitted as light beams 51, which are more obliquely inclined, when emitted from the protection layer 40. In contrast, when a concave lens (e.g., a concave lens 30G) is formed in the pixel as illustrated in FIG. 1B, the light beams 50 that are emitted after penetrating the concave lens 30G are emitted as light beams 52 which are more obliquely inclined in the in-plane direction of the substrate 10 compared with the case where no lenses are provided (dashed lines). Therefore, there is a function of dispersing light beams in an oblique direction in the case where a concave lens is provided as compared with the case where no lenses are provided. More specifically, as a display device, a reduction in the brightness when observed from an oblique direction is suppressed. The “oblique” refers to the direction of an angle inclining in the in-plane direction of the substrate from the front of the display device.

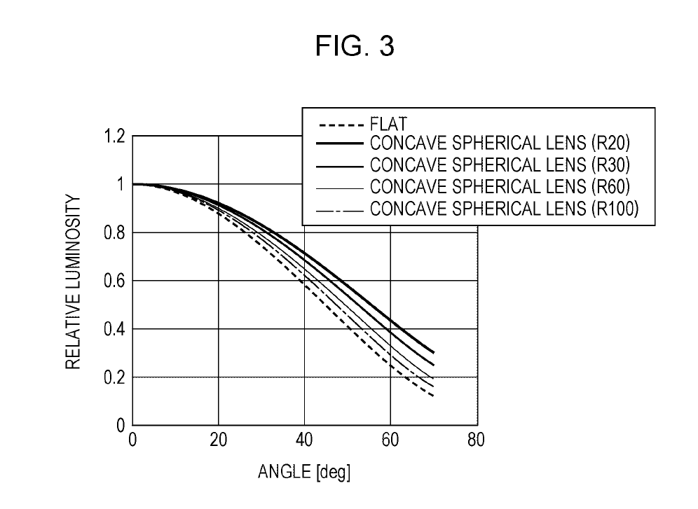

Next, the curvature of the concave lens and the angular dependence of brightness will be described. FIG. 3 is a graph showing the correlation between the radiation angle and the relative brightness when the concave lenses are different from each other in the radius of curvature R. In FIG. 3, the “flat” refers to the case where no lenses are formed. As the concave lenses for use in the measurement, four kinds of lenses with a radius of curvature R of 20 μm, 30 μm, 60 μm, and 100 μm were prepared. In the configuration of the lenses having the radius of curvature mentioned above, the pitch of the pixels was 31.5 μm, the maximum width of the concave lenses was 31.5 μm, and the width of the pixels was 16.5 μm. The second electrode 15 contains a mixture of indium oxide and zinc oxide, in which the refractive index was 1.9 and the film thickness was 0.05 μm. The protection layer 40 contains nitride silicon, in which the refractive index was 1.83 and the film thickness was 0.18 μm. The lens member 30 contains epoxy resin, in which the refractive index was 1.54 and the minimum film thickness was 10 μm. The relative brightness refers to a relative brightness when the brightness at a radiation angle of zero (front) in each composition was 1.

As illustrated in FIG. 3, the relative brightness is more difficult to decrease in the case where the lenses are formed (solid line) as compared with the case where the lenses are not formed (dashed lines). FIG. 3 further shows that, also in the case where the concave lenses are formed, the relative brightness is difficult to decrease when the radius of curvature of the concave lenses is smaller. This shows that the radiation characteristics due to the concave lens are higher in a concave lens with a small radius of curvature than a lens with a large radius of curvature. More specifically, the radiation characteristics become higher in the order of a configuration in which no lenses are provided, a configuration in which a concave lens with a large radius of curvature is provided, and a configuration in which a concave lens with a small radius of curvature is provided. Therefor, the relative brightness is difficult to decrease even when obliquely observed in a pixel having a lens with higher radiation characteristics.

In contrast, the angular dependence of brightness of the organic EL element generally changes depending on the emission color. This is considered to be caused by the fact that the light absorption and the light transmittance have chromatic dispersion due to an organic compound layer, such as the light emitting layer or the hole transporting layer, and the materials or the film thickness of the electrodes and the like of the organic EL element. Moreover, it is considered that the shape of the spectra emitted by the light emission materials of the light emitting layers of the organic EL elements of the respective colors are different from each other, for example.

In the display device of this embodiment, a lens whose radiation characteristics are adjusted is provided in each pixel corresponding to the color emitted by each pixel in such a manner that the differences of the angular dependence of brightness of the organic EL elements that emit different colors is made small. More specifically, a lens with high radiation characteristics is provided in a pixel having an organic EL element in which the angular dependence of brightness is high (large reduction in relative brightness) and a lens with low radiation characteristics is provided in a pixel having an organic EL element in which the angular dependence of brightness is low (small reduction in relative brightness). When the radiation characteristics are controlled by the radius of curvature of the concave lens, a concave lens with a small radius of curvature is provided in a pixel having an organic EL element in which the angular dependence of brightness is low and a concave lens with a large radius of curvature is provided in a pixel having an organic EL element in which the angular dependence of brightness is high.

For example, the case is considered where the angular dependence of brightness varies in each color in a display device having, in each pixel of the pixel unit, an organic EL element which emits red (hereinafter referred to as a B element), an organic EL element which emits green (hereinafter referred to as a G element), an organic EL element which emits blue (hereinafter referred to as an R element). More specifically, the case is considered where the angular dependence of brightness becomes larger in the order of the R element, the G element, and the B element (Angular dependence of R element<Angular dependence of G element<Angular dependence of B element). In this case, the radiation characteristics of a lens to be provided may be simply increased in the order of the R element, the G element, and the B element (Radiation characteristics of the lens of the R element<Radiation characteristics of the lens of the G element<Radiation characteristics of the lens of the B element). By this configuration, in the pixel having the B element provided with a lens with high radiation characteristics, a reduction in the relative brightness is suppressed and the angular dependence of brightness thereof can be brought close to the angular dependence of brightness of the R element. Similarly, also in the pixel having the G element, the angular dependence of brightness thereof can be brought close to the angular dependence of brightness of the R element. More specifically, the angular dependence of brightness of the B element and the G element becomes close to the angular dependence of brightness of the R element. Therefor, even when white color which is a mixed color of red color, green color, and blue color is observed from an oblique angle relative to the display device, the white color shift is suppressed. A more specific description is as follows.

The chromaticity coordinate of each color when observed at the front is, in terms of CIExy, red (0.67,0.33), green (0.21,0.71), and blue (0.14,0.08). When white color of a chromaticity coordinate (0.31,0.33) is displayed, the brightness ratio of red, green, and blue is 3:6:1. in such a case, when a display device is observed from an oblique angle, e.g., an angle inclining from the front by 50°, for example, the chromaticity coordinate of each color is as follows: red (0.65,0.35), green (0.18,0.66), and blue (0.15,0.05). The brightness ratio of red, green, and blue at the angle is 1.26:2.04:0.23. The relative brightness ratio to the brightness of each color when observed at the front is 0.42:0.34:0.23. More specifically, when observed at the angle inclining from the front by 50°, the brightness ratio greatly changes as compared with the brightness ratio at the front in displaying white color, resulting in considerable changes in the chromaticity. Therefor, the brightness ratio at the front cannot be maintained in the case where a display device is observed at the angle inclining from the front by 50°, the white color shift arises.

Then, in order to maintain the brightness ratio of red, green, and blue at 3:6:1 and obtain the white color close to the chromaticity coordinate (0.31,0.33) even when observed from an oblique angle, the angular dependence of brightness of each color is made the same. The reduction ratio of the relative brightness of each color when observed at the angle inclining from the front by 50° is as follows 58% in red, 66% in green, and 77% in blue. In order to make the reduction ratio of the relative brightness of green and blue the same as that of the relative brightness of red, the reduction ratio of the relative brightness is made the same by suppressing a reduction in brightness of green and blue by 11% and 19%, respectively, and thus the difference of the angular dependence of brightness becomes small. Therefor, the brightness ratio when observed at the front can be maintained in the case where a display device is observed at the angle inclining from the front by 50° and the white color shift can be reduced. For the white color shift, the CIE 1976 UCS chromaticity coordinate (hereinafter referred to as an u′v′ chromaticity coordinate) (u′, v′) is generally used and the relationship with the CIExy chromaticity coordinate (x, y) is as follows.

$${u}^{′} = \frac{4 x}{- 2 x + 12 y + 3} , {v}^{′} = \frac{9 y}{- 2 x + 12 y + 3} \qquad [ Equation 1 ]$$

Specifically, the white CIExy chromaticity coordinate (0.31,0.33) is (0.20,0.47) in the u′v′ chromaticity coordinate.

It can be said that the white color shift is sufficiently suppressed when the chromaticity difference δu′v′ represented by a relational expression (Equation 2) of the chromaticity (u′₀, v′₀) observed at the front in the u′v′ chromaticity coordinate and the chromaticity (u′_{θ}, v′_{θ}) observed at an angle θ inclining from the front is 0.015 or lower at θ=50°.

δu′v′=\sqrt{(u′_{θ}−u′₀)²+(v′_{θ}−v′ₒ)²} [Equation 2]

The radiation characteristics of the lens are is not necessarily required to change for every color and may be adjusted as appropriate as required. For example, even when the angular dependence of brightness of the R element, the G element, and the B element is different from each other, the radiation characteristics of the lenses of the B element and the G element are made the same and only the radiation characteristics of the lens provided in the R element may be changed, for example.

In general, the angular dependence of brightness is larger in an organic EL element which emits a light beam of a short wavelength than in an organic EL element which emits a light beam of a long wavelength (Angular dependence of the R element<Angular dependence of the G element<Angular dependence of the B element). Therefor, the angular dependence of brightness becomes larger in the order of the R element, the G element, and the B element. Therefor, it is desirable to enlarge the radiation characteristics of the lens to be provided in the order of the R element, the G element, and the B element (Radiation characteristics of the lens of the R element, Radiation characteristics of the lens of the G element<Radiation characteristics of the lens of the B element). A configuration may be acceptable in which no lenses are provided in the R element.

The radiation characteristics can also be adjusted by a configuration in which a concave lens is provided and a configuration in which a concave lens is not provided. More specifically, a concave lens may be provided in a pixel having an organic EL element with high angular dependence of brightness and a concave lens may not be provided in a pixel having an organic EL element with low angular dependence of brightness.

The substrate 10 may be an insulating substrate on which a switching element (not illustrated), such as TFT or MIM, is formed, and contains glass, plastic, or the like, or may be a silicon substrate on which a transistor is formed. The substrate 10 may have an interlayer insulation film having a contact hole for electrically connecting the switching element and the first electrode 11. The substrate 10 may further have a planarization film for planarizing irregularities of the switching element.

For the first electrode 11, a metal layer containing a metal simple substance, such as Al, Cr, or Ag, and an alloy thereof can be used. A configuration can also be employed in which a transparent conductive oxide layer, such as a compound layer of indium oxide and tin oxide or a compound layer of indium oxide and zinc oxide, is laminated on the metal layer. The film thickness of the first electrode 11 is suitably 50 nm or more and 200 nm or lower. The “transparent” refers to having a light transmittance of 40% or more in a visible light region (Wavelength of 400 nm to 780 nm).

The hole transporting layer 12 contains a single layer or two or more layers of an organic compound having hole injection properties and hole transportation properties. In contrast, the electron transporting layer 14 contains a single layer or two or more layers of an organic compound having electron injection properties and electron transportation properties. In order to suppress the movement of electrons from the light emitting layer to the anode side, an electron blocking layer can also be provided as the hole transporting layer 12 as required. A hole blocking layer can also be provided as the electron transporting layer 14. Moreover, as the hole transporting layer 12 and the electron transporting layer 14, an exciton blocking layer for suppressing the diffusion of excitons occurring in the light emitting layer can also be provided.

The light emitting layer 13R which emits red, the light emitting layer 13G which emits green, and the light emitting layer 13B which emits blue are not particularly limited and known materials can be applied. For example, a single layer of materials having both light emitting properties and carrier transportation properties or a mixed layer of light emitting materials, such as fluorescent materials or phosphorescent materials, and host materials having carrier transportation properties can be applied.

For each of the light emitting layers 13R, 13G, and 13B, the hole transporting layer 12, and the electron transporting layer 14, known materials can be used and, as film forming techniques, known film forming techniques, such as vapor deposition or transfer, can be used. The film thickness of each layer is suitably set to the optimal film thickness in order to increase the light emission efficiency of the organic EL elements of the respective colors and is suitably 5 nm or more and 100 nm or lower.

For the second electrode 15, a metal thin film containing a metal simple substance, such as Al, Cr, or Ag, and an alloy thereof can be used. Particularly in a metal thin film containing Ag, the absorptivity is low and the specific resistance is also low. Therefore, the metal thin film is suitable as the second electrode 15. The film thickness of the second electrode 15 is suitably 5 nm or more and 30 nm or lower. The second electrode 15 may have a configuration in which the above-described metal thin film and the transparent conductive oxide layer, such as the compound layer of indium oxide and tin oxide or the compound layer of indium oxide and zinc oxide, are laminated or a configuration in which only the transparent conductive oxide layer is provided.

For the protection layer 40, known materials and film forming techniques can be used. As an example, a method for forming a film of silicon nitride or silicon oxynitride by a CVD device is mentioned. The film thickness of the protection layer 40 is suitably 0.5 μm to 10 μm in order to have protection capability.

For the lens member 30, thermosetting resin with little moisture content, thermoplastic resin, and photocuring resin can be used. The film thickness of the lens member 30 is suitably from 10 μm to 100 μm. When the thermosetting resin and the photocuring resin are used, a spin coating method, a dispense method, and the like can be used as the film forming methods. Moreover, a method can also be used which includes sticking a thermoplastic resin film having a film thickness of about 10 μm to about 100 μm under vacuum onto the protection layer 40. As a specific resin material, epoxy resin and butyl resin are suitably used.

As methods for manufacturing the concave lenses 30R, 30G, and 30B, the following methods are mentioned:
(1) A method including preparing a mold for a lens, and pressing the mold to a resin layer to thereby form the resin into a lens shape;
(2) A method including heat treating a resin layer patterned by photolithography or the like, and then transforming the resin layer into a lens shape by reflow;
(3) A method including exposing a photocuring resin layer formed with a uniform thickness with a light beam having a distribution in the in-plane direction, and developing the resin layer to thereby form a lens;
(4) A method including processing the surface of the resin material formed with a uniform thickness using ion beam, electron beam, laser, or the like into a lens shape;
(5) A method including adding dropwise an appropriate amount of resin to each pixel to thereby form a lens in a self-aligned manner; and
(6) A method including preparing a resin sheet on which a lens is formed beforehand separately from a substrate on which an organic EL element is formed, aligning the substrate and the resin sheet, and the sticking them to each other to thereby form a lens.

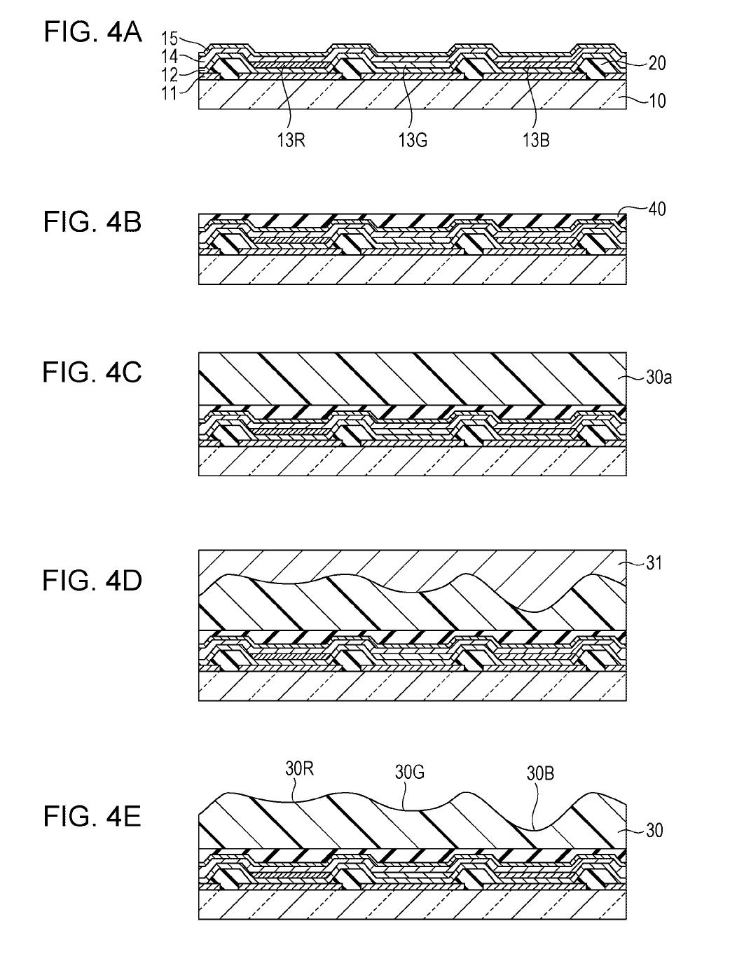

The case where the method of (1) above is used for manufacturing the display device of this embodiment will be described with reference to FIGS. 4A to 4E. A method for forming the first electrode 11 to the second electrode 15 on the substrate 10 is omitted because well-known methods are used.

First, as illustrated in FIG. 4A, two or more top emission type organic EL elements are formed on the substrate 10. Next, as illustrated in FIG. 4B, the protection layer 40 is formed throughout a display region in such a manner as to cove the organic EL elements. The protection layer 40 protects the organic EL elements from moisture or oxygen in the air or moisture inherent in a resin material 30a to be formed later and also has a planarization function for forming a lens on the protection layer 40 with high accuracy.

Next, as illustrated in FIG. 4C, the resin material 30a serving as the base for the lens member 30 is formed on the protection layer 40. Then, as illustrated in FIG. 40, a mold 31 for molding the concave lenses 30R, 30G, and 30B is prepared, and then the mold 31 is pressed against the resin material 30a in such a manner that air bubbles are not mixed in the resin material 30a. On the surface of the mold 31 in contact with the resin material 30a, convex portions are formed corresponding to each pixel, and the radius of curvature of each convex portion is adjusted according to the radiation characteristics of the concave lens to be provided in each pixel.

The mold 31 can be formed with a general metal but when photocuring resin is used for the resin material 30a, the mold 31 is suitably formed with a quartz substrate because the mold 31 needs to transmit a light beam. In order to increase the separability of the mold 31 from the lens member 30, a film of fluororesin or the like may be formed on the surface of the mold 31.

When thermosetting resin is used for the resin material 30a, the resin material 30a is cured by heating the same to 80° C. in a state where the top of the convex portion in the mold 31 is almost in agreement with the center of the corresponding pixel. Since the heat-resistant temperature of organic compounds constituting common organic EL elements is about 100° C., the curing temperature is suitably about 80° C., which is lower than the heat-resistant temperature.

Next, as illustrated in FIG. 4E, the mold 31 is removed from the cured lens member 30. Thus, the concave lenses 30R, 30G, and 30B are formed on the surface of the lens member 30 corresponding to each pixel.

When the concave lenses 30R, 30G, and 30B are formed with resin, it is desirable to provide a second protection layer (not illustrated) containing inorganic substances on the lenses in order not to damage the shape of the lenses. The second protection layer can be formed with the same materials and the same methods as those of protection layer 40.

### Second Embodiment

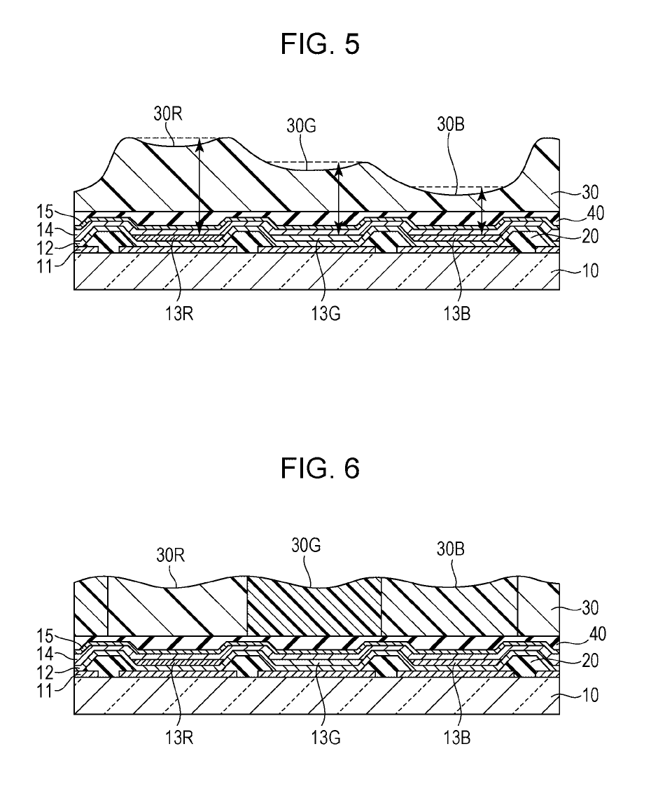

FIG. 5 is a partial sectional schematic view of a display device of this embodiment. The first embodiment relates to the display device in which the radius of curvature of the lenses is varied in the organic EL elements of the respective colors to thereby control the radiation characteristics, whereby the difference in the angular dependence of brightness of the organic EL elements of the respective colors is made small. In contrast, this embodiment relates to a display device in which the distance between a lens and a light emitting layer of each organic EL element is varied in the organic EL elements of the respective colors to thereby control the radiation characteristics, whereby the difference in the angular dependence of brightness of the organic EL elements of the respective colors is made small.

In general, the radiation characteristics of the lens become small with an increase in the distance between the concave lens and the light emitting point (or light emitting surface). Therefor, in a pixel having an organic EL element with high angular dependence of brightness (a large reduction in relative brightness), the lens is disposed at a position near the light emitting layer in such a manner that the radiation characteristics become high. In a pixel having an organic EL element with low angular dependence of brightness (a small reduction in relative brightness), the lens is disposed at a position distant from the light emitting layer in such a manner that the radiation characteristics become small. The distance between the concave lens and the light emitting layer is a distance (the length of the arrow) between the dashed line and the light emitting layer illustrated in FIG. 5. More specifically, the distance between the concave lens and the light emitting layer is a distance between the surface of a lens portion furthest from the light emitting layer of the surface of the lens portion corresponding to a light emitting region (pixel) and the light emitting layer.

Specifically, the case is considered where the angular dependence of brightness becomes larger in the order of the R element, the G element, and the B element (Angular dependence of the R element<Angular dependence of the G element<Angular dependence of the B element). As illustrated in FIG. 5, the distance of the concave lenses 30R, 30G, and 30B and each of the light emitting layers 13R, 13G, and 13B is made smaller in the order of the R element, the G element, and the B element (Distance between the lens and the light emitting layer of the R element>Distance between the lens and the light emitting layer of the G element>Distance between the lens and the light emitting layer of the B element). Due to this configuration, in the pixel having the B element provided with the lens with high radiation characteristics, the reduction in the relative brightness is suppressed and the angular dependence of brightness thereof can be brought close to that of the R element. Similarly, also in the pixel having the G element, the angular dependence of brightness thereof can also be brought close to that of the R element. More specifically, since the angular dependence of brightness of the B element and the G element becomes close to the angular dependence of brightness of the R element, the white color shift is suppressed even when white color which is a mixed color of red, green, and blue is observed from an oblique angle relative to the display device.

The display device of this embodiment can also be manufactured with the same manufacturing method as in the first embodiment. In this embodiment, the radius of curvature of the concave lenses may be the same in each pixel or may be different from each other. In particular, it is desirably configured such that a concave lens with a small radius of curvature is provided in a pixel having an organic EL element with low angular dependence of brightness and a concave lens with a large radius of curvature is provided in a pixel having an organic EL element with high angular dependence of brightness as in the first embodiment. Third embodiment

FIG. 6 is a partial sectional schematic view of a display device of this embodiment. This embodiment relates to a display device in which the refractive index of a lens is varied in the organic EL elements of the respective colors to thereby control the radiation characteristics, whereby the difference of the angular dependence of brightness of organic EL elements of the respective colors is made small.

In general, the radiation characteristics of the lens become large with an increase in the refractive index of the concave lens. Therefor, it is configured such that, in a pixel having an organic EL element with high angular dependence of brightness (a large reduction in relative brightness), a concave lens having a high reflective index is provided in such a manner that the radiation characteristics become high. In a pixel having an organic EL element with low angular dependence of brightness (a small reduction in relative brightness), a concave lens having a low reflective index is provided.

Specifically, the case is considered where the angular dependence of brightness becomes larger in the order of the R element, the G element, and the B element (Angular dependence of the R element<Angular dependence of the G element<Angular dependence of the B element). In this case, as illustrated in FIG. 6, the refractive index of the concave lenses is increased in the order of the R element, the G element, and the B element (Refractive index of the lens of the R element<Refractive index of the lens of the G element<Refractive index of the lens of the B element). Due to this configuration, in the pixel having the B element provided with the lens with a high reflective index and high radiation characteristics, the reduction in the relative brightness is suppressed and the angular dependence of brightness thereof can be brought close to that of the R element. Similarly, also in the pixel having the G element, the angular dependence of brightness thereof can also be brought close to that of the R element. More specifically, since the angular dependence of brightness of the B element and the G element becomes close to the angular dependence of brightness of the R element, the white color shift is suppressed even when white color which is a mixed color of red, green, and blue is observed from an oblique angle relative to the display device.

The display device of this embodiment can also be manufactured with the same manufacturing method as in the first embodiment. In this embodiment, the radius of curvature of the concave lenses may be the same in each pixel or may be different from each other. In particular, it is desirably configured such that a concave lens with a small radius of curvature is provided in a pixel having an organic EL element with low angular dependence of brightness and a concave lens with a large radius of curvature is provided in a pixel having an organic EL element with high angular dependence of brightness as in the first embodiment. The third embodiment may be combined with the configuration of the second embodiment or may be combined with a combination of the configuration of the first embodiment and the configuration of the second embodiment.

Mentioned as methods for controlling the refractive index is a method for adjusting the refractive index with the refractive index of the resin forming the lens. Furthermore, mentioned is a method including blending inorganic materials in the resin forming the lens to thereby adjust the refractive index or the content in the resin of the inorganic materials. Mentioned as the inorganic materials are, for example, titanium oxide (2.90), ITO (2.12), mercury sulfide (2.81), cobalt green (1.97), cobalt blue (1.74), and the like.

### Other Embodiments

As described above, the radiation characteristics can be controlled by a method different from the methods of the first embodiment to the third embodiment. For example, when the radiation characteristics are controlled by a region occupied by the lens of the pixel region, the effects of the invention are demonstrated in the case of the following configuration. More specifically, the region occupied by the lens may be enlarged in a pixel having an organic EL element with low angular dependence of brightness and the region occupied by the lens may be reduced in a pixel having an organic EL element with high angular dependence of brightness. Due to the configuration, the ratio of light beams that penetrate the lens among light beams emitted from the light emitting regions (pixels) can be adjusted, and thus the radiation characteristics of the entire pixel are controlled.

Moreover, in the configuration described above, the lens is provided in accordance with the angular dependence of brightness of color in which the reduction in the brightness is small. However, even in a configuration such that the lens is provided in accordance with the angular dependence of brightness of color in which the reduction in the brightness is large, the white color shift can be reduced. Specifically, the following configuration is mentioned.

More specifically, the radiation characteristics can also be adjusted by providing both a configuration such that a concave lens is provided and a configuration in which a convex lens is provided. The radiation characteristics of the convex lens are lower and the light gathering characteristics thereof are higher than the configuration in which a concave lens is provided and than the configuration in which no lenses are provided. By utilizing the characteristics, a convex lens may be provided in a pixel having an organic EL element with low angular dependence of brightness and a concave lens may be provided in a pixel having an organic EL element with high angular dependence of brightness.

The radiation characteristics (light gathering characteristics) of pixels can also be controlled only by a convex lens by utilizing the fact that, in the convex lens, the radiation characteristics become lower as the radius of curvature becomes lower (the light gathering characteristics become higher). More specifically, it may be configured such that a convex lens with a small radius of curvature is provided in a pixel having an organic EL element with low angular dependence of brightness and a convex lens with a large radius of curvature is provided in a pixel having an organic EL element with high angular dependence of brightness. Even in the configuration, the difference of the angular dependence of brightness of the organic EL elements of the respective colors can be made small.

Mentioned as the display device of the invention are television sets, personal computers, imaging devices, display portions of cellular phones, and portable game machines. In addition, portable music playback devices, Personal Digital Assistant (PDA), car navigation systems, and the like are mentioned.

### EXAMPLES

### Example 1

This Example describes an example in which the difference of the angular dependence of brightness of organic EL elements using lenses different in the radius of curvature will be described with reference to FIGS. 4A to 4E.

First, a low-temperature polysilicon TFT was formed on a glass substrate, and then an interlayer insulation film containing nitride silicon and a planarization film containing acrylic resin were formed thereon in this order, thereby creating a substrate 10 illustrated in FIG. 4A. An ITO film/AlNd film was formed on the substrate 10 by sputtering with a thickness of 38 nm/100 nm. Subsequently, the ITO film/AlNd film was patterned for every pixel to form first electrodes 11.

Acrylic resin was applied onto the first electrodes 11 by spin coating. The acrylic resin was patterned by lithography in such a manner that openings (the openings correspond to the pixels) were formed in portions where the first electrodes 11 were formed to thereby form an insulation layer 20. The pitch of the pixels was 30 μm and the size of the exposed portions of the first electrodes 11 formed by the openings was 10 μm. The product was cleaned through ultrasonic cleaning with isopropyl alcohol (IPA), cleaned through boiling, and then dried. Further, the product was subjected to UV/ozone cleaning, and the following organic EL layers were formed by vacuum deposition. The degree of vacuum and the deposition rate during film formation of each organic compound layer was 1×10 to 3.0×10⁻⁴ Pa was 0.2 to 0.5 nm/sec, respectively.

First, a compound 1 of the following structural formula was formed into a film with a thickness of 87 nm in common on the first electrodes 11 as the hole transporting layer 12 on the entire display region.

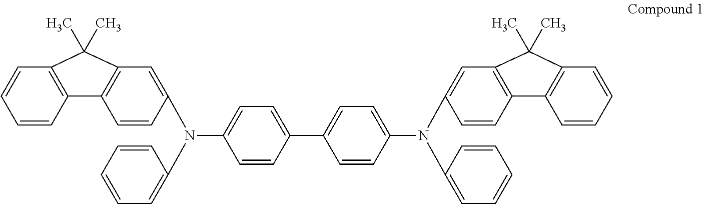

Next, CBP and Ir(piq)₃ were formed into a film as a red light emitting layer 13R on a portion serving as a pixel which emits red by co-deposition using a vapor deposition mask in such a manner that the weight ratio was 91:9 and the thickness was 30 nm. Then, Alq₃ and coumarin 6 were formed into a film as a green light emitting layer 13G on a portion serving as a pixel which emits green by co-deposition using a vapor deposition mask in such a manner that the weight ratio was 99:1 and the thickness was 40 nm. Furthermore, BAlq and perylene were formed into a film as a blue light emitting layer 13B on a portion serving as a pixel which emits blue by co-deposition using a vapor deposition mask in such a manner that the weight ratio was 97:3 and the thickness was 25 nm.

Subsequently, Bphen was formed into a film with a thickness of 10 nm as a common electron-transporting layer 14 on the entire display region. Furthermore, Bphen and Cs₂CO₃ were formed into a film thereon as a common electron injection layer (a part of the electron-transporting layer 14) by co-deposition (Weight ratio of 90:10) with a thickness of 40 nm.

Next, the above-described product was transferred to a sputtering apparatus while the vacuum state was maintained, and then Ag and ITO were successively formed into a film as a second electrode 15 with a thickness of 10 nm and 50 nm, respectively.

Next, as illustrated in FIG. 4B, a protection layer 40 containing nitride silicon was formed by a plasma CVD method using SiN₄ gas, N₂ gas, and H₂ gas.

Then, as illustrated in FIG. 4C, a thermosetting epoxy resin material having a viscosity of 3000 mPa·s was applied as the resin material 30a in a nitrogen atmosphere with a dew point of 60° C. using a dispenser (Product name: SHOT MINI SL, manufactured by Musashi Engineering, Inc.).

Before curing the resin material 30a by heating, the mold 31, separately prepared, for molding the concave lenses, 30R, 30G, and 30B was pressed against the surface of the resin material 30a as illustrated in FIG. 40. In pressing, positioning was performed by aligning an alignment mark formed on the mold 31 with an alignment mark formed on the substrate 10. As a result, the concave lenses 30R, 30G, and 30B were formed corresponding to pixels. On the mold 31, convex portions were formed at the same pitch as the pitch of the pixels and the surface of the mold 30 was coated with fluororesin as a release agent. The radius of curvature of each of the convex portions corresponding to the red, green, and blue pixels of the mold 31 was 100 μm, 45 μm, and 25 μm, respectively. The film thickness of the lens member 30 was 20 μm.

Here, in consideration of the environment of a clean room and a processing apparatus, the minimum thickness (the thickness in the thinnest portion) of the lens member 30 was set to 10 μm for the purpose of planarizing with the resin material 30a even when there are foreign substances or the like.

Next, in the state where the mold 31 was pressed against the resin material 30a, heating was performed at a temperature of 100° C. for 15 minutes under a vacuum environment to cure the resin material 30a, whereby the lens member 30 was formed. Thereafter, the mold 31 was removed from the lens member 30, thereby forming the concave lenses 30R, 30G, and 30B as illustrated in FIG. 4E. The radius of curvature of the concave lenses 30R, 30G, and 30B was 100 μm, 45 μm, and 25 μm, respectively.

Furthermore, a protection layer (not illustrated) containing inorganic materials containing nitride silicon was formed by a plasma CVD method using SiH₄ gas, N₂ gas, and H₂ gas. The film thickness of the protection layer was 1 μm and was formed in such a manner as to cover the entire surface of the display region.

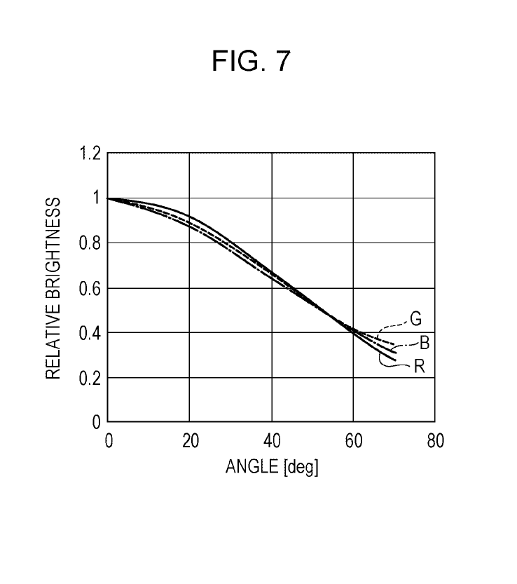

The properties of the display device thus manufactured of the invention were evaluated, and the results are collectively shown in Table 1. Here, the properties at an angle inclining from the front by 50° were compared. FIG. 7 shows the angular dependence of brightness of each color in the display device of this Example.

The relative brightness (Front brightness: 1) in Table 1 is the value obtained by standardizing the brightness of each color at an inclination of 50° under the conditions where the brightness of each color required for obtaining white color (0.31,0.33) at the front was 1.

The δu′v′ indicates a color difference between the white color when the display device was observed from the front and the white color when the display device was observed at 50°. As a Comparative Example, the evaluation results of a display device in a configuration such that no lenses are provided in each pixel are also shown in Table 1.

TABLE 1

| | | Example 1 | | Comparative Example | |
|---|---|---|---|---|---|
| | Front | 50° | Relative | 50° | Relative |
| | chromaticity | chromaticity | brightness | chromaticity | brightness |
| Red | (0.67, 0.33) | (0.66, 0.34) | 0.87 | (0.65, 0.35) | 0.42 |
| Green | (0.21, 0.70) | (0.20, 0.69) | 0.87 | (0.18, 0.66) | 0.34 |
| Blue | (0.13, 0.08) | (0.13, 0.07) | 0.87 | (0.15, 0.05) | 0.23 |
| White | (0.31, 0.33) | (0.30, 0.32) | 0.56 | (0.31, 0.30) | 0.23 |

| | | | |
|---|---|---|---|
| δu′v′ | — | 0.010 | 0.017 |

Table 1 and FIG. 7 show that, in the display device of this Example, the difference of the angular dependence of brightness among the respective colors is made smaller than that of the Comparative Example and the white color shift is reduced. More specifically, in Example 1, when the display device was observed at an inclination of 50°, the relative brightness is comparable in each color, i.e., a reduction ratio of brightness is comparable in each color, and therefore the balance of white display is maintained also in this direction, so that the white color shift is suppressed.

### Example 2

This Example is an example in which the difference of the angular dependence of brightness of the organic EL elements is made small by adjusting the distance from the light emitting layer to the concave lens.

This Example is manufactured by the same processes, except that the surface shape of the lens mold 31 is different from that of Example 1. In this Example, convex portions are formed with the same pitch as the pixel pitch and the height of the convex portions is different from that of Example 1. The height was set in such a manner that the distance from the concave lens to the light emitting layer was 60 μm, 48 μm, and 25 μm, respectively, in the pixels emitting red, green, and blue.

The properties of the display device thus manufactured were evaluated, and the results are collectively shown in Table 2. The Comparative Example is the same as in Example 1.

TABLE 2

| | | Example 2 | | Comparative Example | |
|---|---|---|---|---|---|
| | Front | 50° | Relative | 50° | Relative |
| | chromaticity | chromaticity | brightness | chromaticity | brightness |
| Red | (0.67, 0.33) | (0.66, 0.34) | 0.87 | (0.65, 0.35) | 0.42 |
| Green | (0.21, 0.70) | (0.20, 0.69) | 0.83 | (0.18, 0.66) | 0.34 |
| Blue | (0.13, 0.08) | (0.13, 0.07) | 0.81 | (0.15, 0.05) | 0.23 |
| White | (0.31, 0.33) | (0.30, 0.31) | 0.54 | (0.31, 0.30) | 0.23 |

| | | | |
|---|---|---|---|
| δu′v′ | — | 0.011 | 0.017 |

Table 2 shows that, in the display device of this Example, the difference of the angular dependence of brightness among the respective colors is made smaller than that of the Comparative Example and the white color shift is reduced.

### Example 3

This Example is an example in which the difference of the angular dependence of brightness of the organic EL elements is made small by adjusting the refractive index of the concave lens.

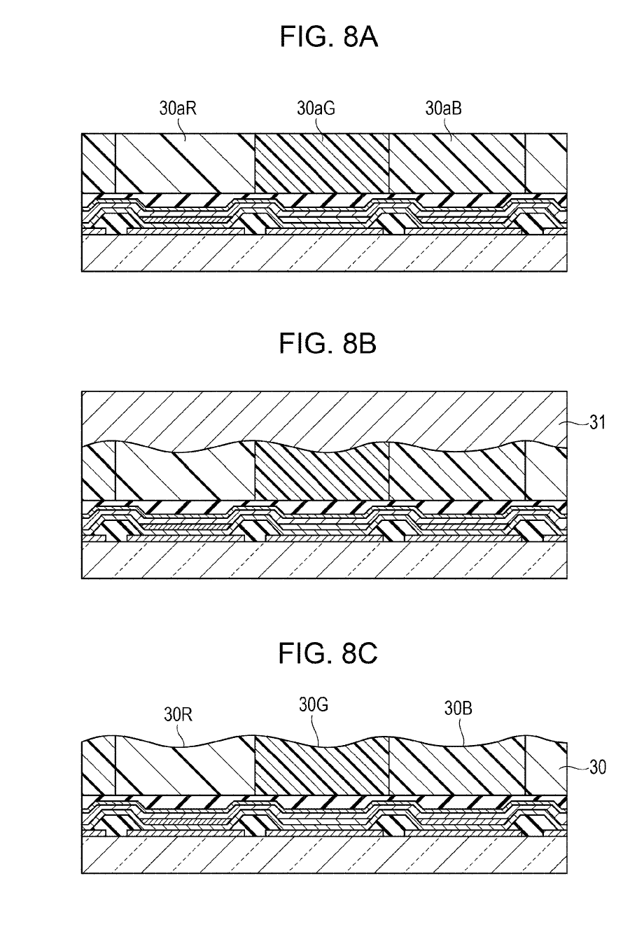

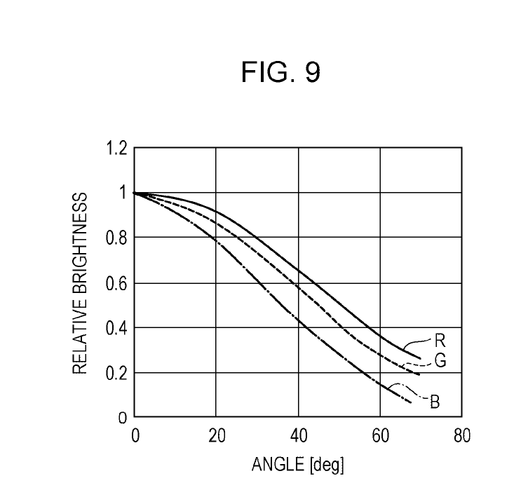

This Example is manufactured by the same processes, except that the application process of the lens member and the surface shape of the lens mold 31 are different from those of Example 1. After forming the protection layer 40 similarly as in Example 1, epoxy resins 30aR, 30aG, and 30aB were applied to the position of the corresponding pixels using a nozzle dispenser as illustrated in FIG. 8A. Into the nozzle at the position corresponding to the red pixel, the epoxy resin was charged and, into the nozzles at the position corresponding to the green pixel and the blue pixel, the epoxy resins different in the mixing ratio of titanium oxide particles were charged, and then the epoxy resins were applied. The proportion of the titanium oxide in the epoxy resin charged into the nozzle at the position corresponding to each of the green and blue pixels was 22% by weight and 40% by weight relative to the epoxy resin, respectively.

Next, as illustrated in FIG. 8B, the concave lenses was formed by pressing the mold 31 separately prepared against the surface of the resin member 30a. The mold 31 of this Example had convex portions formed with the same pitch as the pixel pitch.

Next, under the state where the mold 31 was pressed against the resin materials 30aR, 30aG, and 30aB, heating was performed at a temperature of 100° C. for 15 minutes under a vacuum environment to cure the resin materials 30aR, 30aG, and 30aB, whereby the lens member 30 was formed. Thereafter, the mold 31 was removed from the lens member 30, thereby forming concave lenses 30R, 30G, and 30B as illustrated in FIG. 8C. The radius of curvature of the concave lenses 30R, 30G, and 30B was all the same, 50 μm.

In the concave lenses 30R, 30G, and 30B, titanium oxide particles having a refractive index of 2.90 were mixed in epoxy resin having a refractive index 1.54, and the refractive index of the lenses was increased in the order of the R element, the G element, and the B element (Refractive index of the concave lens of the R element<Refractive index of the concave lens of the G element<Refractive index of the concave lens of the B element) by increasing the mixing ratio in the order of the R element, the G element, and the B element.

The properties of the display device thus manufactured were evaluated, and the results are collectively shown in Table 3. The Comparative Example is the same as in Example 1.

TABLE 3

| | | Example 3 | | Comparative Example | |
|---|---|---|---|---|---|
| | Front | 50° | Relative | 50° | Relative |
| | chromaticity | chromaticity | brightness | chromaticity | brightness |
| Red | (0.67, 0.33) | (0.66, 0.34) | 0.87 | (0.65, 0.35) | 0.42 |
| Green | (0.21, 0.70) | (0.20, 0.69) | 0.83 | (0.18, 0.66) | 0.34 |
| Blue | (0.13, 0.08) | (0.13, 0.07) | 0.81 | (0.15, 0.05) | 0.23 |
| White | (0.31, 0.33) | (0.30, 0.31) | 0.54 | (0.31, 0.30) | 0.23 |

| | | | |
|---|---|---|---|
| δu′v′ | — | 0.011 | 0.017 |

Table 3 shows that, in the display device of this Example, the difference of the angular dependence of brightness among the respective colors is made smaller than that of the Comparative Example and the white color shift is reduced.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2010-213896 filed Sep. 24, 2010 and No. 2011-164381 filed Jul. 27, 2011, which are hereby incorporated by reference herein in their entirety.

What is claimed is:

1. A display device, comprising:
two or more pixel units containing two or more pixels different in emission color,
the pixels each having an organic EL element, and
the pixel units each being provided with a lens in such a manner that a difference in an angular dependence of brightness of the organic EL elements for every emission color of the pixels is small.

2. The display device according to claim 1, wherein the lens provided in the pixel in which the angular dependence of brightness is high has higher radiation characteristics than radiation characteristics of the lens provided in the pixel in which the angular dependence of brightness is low.

3. The display device according to claim 1, wherein the pixel in which the angular dependence of brightness is high is provided with a lens having radiation characteristics and the pixel in which the angular dependence of brightness is low is not provided with a lens.

4. The display device according to claim 2, wherein the radiation characteristics are controlled by the radius of curvature of a concave lens, a distance between the concave lens and a light emitting layer, or a refractive index of the concave lens.

5. The display device according to claim 1, wherein the pixel in which the angular dependence of brightness is high is provided with a concave lens whose radius of curvature is smaller than a radius of curvature of a concave lens provided in the pixel in which the angular dependence of brightness is low.

6. The display device according to claim 1, wherein a concave lens provided in the pixel in which the angular dependence of brightness is high is disposed at a position distant from a light emitting layer relative to a concave lens provided in the pixel in which the angular dependence of brightness is low.

7. The display device according to claim 1, wherein a reflective index of a concave lens provided in the pixel in which the angular dependence of brightness is high is higher than a reflective index of the lens provided in the pixel in which the angular dependence of brightness is low.

8. The display device according to claim 2, wherein
the two or more pixels have a pixel which emits red, green, or blue, and
the organic EL element having high large angular dependence of brightness is an organic EL element which emits blue.
